(19) United States
(12) Patent Application Publication
(10) Pub. No.: US 2022/0123209 A1
(43) Pub. Date: Apr. 21, 2022

(54) SELECTOR DEVICES INCLUDING S-DOPED AsSeGeSi CHALCOGENIDES

(71) Applicants: MACRONIX INTERNATIONAL CO., LTD., Hsinchu (TW); INTERNATIONAL BUSINESS MACHINES CORPORATION, Armonk, NY (US)

(72) Inventors: Huai-Yu CHENG, WHITE PLAINS, NY (US); I-Ting KUO, TAOYUAN (TW); Hsiang-Lan LUNG, ARDSLEY, NY (US); Cheng-Wei CHENG, Yorktown Heights, NY (US); Matthew J. BRIGHTSKY, Armonk, NY (US)

(73) Assignees: MACRONIX INTERNATIONAL CO., LTD., Hsinchu (TW); INTERNATIONAL BUSINESS MACHINES CORPORATION, Armonk, NY (US)

(21) Appl. No.: 17/072,906

(22) Filed: Oct. 16, 2020

(51) Int. Cl. H01L 45/00; H01L 27/24

(52) U.S. Cl. CPC H01L 45/142; H01L 27/2481; H01L 45/143; H01L 45/06; H01L 45/1253; H01L 27/2427

(57) ABSTRACT

A switching device having a first electrode, a second electrode, and a switching layer between the first and second electrodes, formed using a chalcogenide composition doped with an element that suppresses oxidation, which results in improved manufacturability and yield. For selector material based on AsSeGeSi or other chalcogenide materials that include selenium or arsenic, or other chalcogenide materials that include selenium or arsenic and silicon, the element added to suppress oxidation can be sulfur.

### BACKGROUND

### Field

The present invention relates to switching devices utilized in integrated circuits, including integrated circuit memory devices.

### Description of Related Art

There are many applications for switching devices, such as transistors and diodes, in integrated circuits. The emergence of new nonvolatile memory (NVM) technologies—such as phase change memory, resistive memory—has been motivated by exciting applications such as storage class memory, solid-state disks, embedded nonvolatile memory and neuromorphic computing. Many of these applications are suggested to be packed densely in vast “crosspoint” arrays which can offer many gigabytes.

In such arrays, access to any small subset of the array for accurate reading or low-power writing requires a strong nonlinearity in the current versus voltage IV characteristics, so that the currents passing through the selected devices greatly exceed the residual leakage through the nonselected devices. This nonlinearity can either be included explicitly, by adding a discrete selector device at each crosspoint, or implicitly with an NVM device which also exhibits a highly nonlinear IV characteristic.

One type of switching device, usable as a switch and as a selector, is known as the ovonic threshold switch OTS, based on ovonic materials, characterized by a large drop in resistance at a switching threshold voltage, and recovery of a high resistance, blocking state when the voltage falls below a holding threshold.

Arsenic Selenium Germanium Silicon (AsSeGeSi) OTS materials show potential for these uses, but these materials are very sensitive to the air.

It is desirable to provide a switching device with good selector characteristics including relatively high threshold voltages, low leakage current, fast switching speeds, along with resistance to degradation in the presence of air and other conditions encountered during manufacturing and during operation in the field.

### SUMMARY

A switching device is described comprising a first electrode, a second electrode, and a switching layer between the first and second electrodes, wherein the switching layer comprises a chalcogenide composition doped with an element that suppresses oxidation, which results in improved manufacturability and yield. For selector material based on AsSeGeSi, or other chalcogenide materials that include selenium or arsenic, or other chalcogenide materials that include selenium or arsenic and silicon, the element added to suppress oxidation can be sulfur. A composition for an OTS switching layer is described that is composed of combination of As, Se, Ge, Si and S.

In embodiments described, a switching layer comprises a composition of arsenic As in a range of 25 at % to 33 at %, selenium Se in a range of 34 at % to 46 at %, germanium Ge in a range of 8 at % to 12 at %, silicon Si in a range of 6 at % to 12 at % and sulfur Sin a range of 1 at % to 5 at %, wherein the atomic percentage is computed from amounts of materials in the switching layer excluding oxygen contaminants formed in manufacture. (If oxygen is present, its contribution to the “100 at %” is excluded, and the contributions of remaining elements are normalized to 100%). The concentration as atomic percent can be measured using Rutherford backscattering spectrometry (RBS) with accuracy sufficient to determine the ranges recited.

The switching material includes a combination of As, Se, Ge, Si and S in amounts sufficient to act as a switching device suitable for use in integrated circuit memory. For example, the switching layer in a thickness less than 50 nm, can be a combination of As, Se, Ge, Si and S in amounts effective to have a threshold voltage greater than 3 V, and an off state current I_{OFF} less than 2 nA at a bias across the switching layer of 2 V, and in some embodiments less than 100 pA.

In embodiments described, a barrier layer is formed between the switching layer and one of the first and second electrodes, which can be carbon or other barrier materials. In a manufacturing method, the switching layer is deposited by sputtering using a sputter target consisting of, or comprising, a combination of As, Se, Ge, Si and S, and the barrier layer of carbon is in situ deposited, by sputtering in the same chamber.

A memory device is described including a first electrode, a second electrode, a memory element in contact with the first electrode, a switching layer between the first and second electrodes, the switching layer comprising a composition as described herein.

An OTS material is provided based on an As—Se—Ge—Si material system with a Sulfur additive.

Other aspects and advantages of the present invention can be seen on review of the drawings, the detailed description and the claims, which follow.

### BRIEF DESCRIPTION OF THE DRAWINGS

FIG. 1 is a simplified diagram of a cross-section of a switching device including a switching layer of a composition comprising S-doped AsSeGeSi material.

FIG. 2A is a graph of threshold voltage distributions vs cycle numbers for a switching device as described herein, for 1.2 at. % S in AsSeGeSi material 30 nm thick.

FIG. 2B is a graph of off-current distributions vs cycle numbers for a switching device as described herein, for 1.2 at. % S in AsSeGeSi material 30 nm thick.

FIG. 3 is a force V/sense I graph for cycling of an OTS switch comprising materials described herein, for 1.2 at. % S in AsSeGeSi material 30 nm thick.

FIG. 4 is a simplified 3D perspective of a memory cell in a crosspoint memory device including a switching device as described herein.

FIGS. 5A and 5B are simplified layer diagrams for alternative stack configurations of a crosspoint memory device including a switching device as described herein.

FIG. 6 is a simplified flowchart for manufacturing a switching device as described herein.

FIG. 7 is a simplified block diagram of an integrated circuit memory device comprising a 3D memory utilizing switching devices as described herein.

### DETAILED DESCRIPTION

Selector materials based on AsSeGeSi material have good performance, but low yield because the material is easy to oxidize, when the material is exposed to moisture in the air after thin film deposition or processing. Also, the oxidation of the material results in release of toxic AsH₃ or SeH₂

It is believed the following reaction would happen when the film is exposed to moisture:

SiSe+H₂O→SiO₂+SeH₂

SiAs+H₂O→SiO₂+AsH₃

Also, this process can dramatically change the electrical properties of a selector implemented using the material. Oxidization of AsSeGeSi OTS material may decrease the threshold voltage Vth and dramatically increase leakage current I_{OFF}. In severe cases (including oxygen level >30 at. %), the OTS device can becomes a “short” after a first forming process used to activate the switching layer or associated memory cells during manufacturing.

A detailed description of embodiments of an OTS selector material having an element added to suppress oxidation is provided. For selector material based on AsSeGeSi material, or other chalcogenide materials that include selenium or arsenic, or other chalcogenide materials that include selenium or arsenic and silicon, the element added to suppress oxidation can be sulfur. A special OTS material is provided by doping S (small amount) into an AsSeGeSi system to suppress the oxidization, and preserve good selector properties.

With 3˜4 at. % S doping into specific AsSeGeSi compositions used as selector, the selector shows very good Vth and low I_{OFF} (90 pA@2V) at 20 nm OTS thickness, which is suitable for 3D-crosspoint memory technology and other memory device architectures.

Compositions have been formed and tested as shown in the following table:

Optimized AsSeGeS Composition with S doping

| | | | | | | | AsH3 outgassing (ppb), in- | 20 nm OTS, |
|---|---|---|---|---|---|---|---|---|
| | As | Se | Ge | Si | S | O | situ capped 30 nm Carbon | Vth/IOFF |
| Films #1 | 25.1 | 34.3 | 8.6 | 10.1 | 1.2 | 20.7 | 1.6 ppb max/0 in 10 mins | 3.5 V/2 nA @ 2 V |
| Films #2 | 30.3 | 45.5 | 11 | 6.1 | 3.9 | 3.3 | 0 | 3.7 V/90 pA @ 2 V |

It is shown therefore that increasing the doping amount of the S from 1.2 at % to 3.9 at % results in substantial decrease in detected oxygen content in the manufacture film, from 20.7 at % to 3.3 at %. Also, the IOFF characteristic for a 20 nm film is reduced from about 2 nA to 90 pA.

A class of materials is described having compositions (excluding oxygen contaminants) as follows:

As: 25 at % to 33 at %

Se: 34 at % to 46 at %

Ge: 8 at % to 12 at %

Si: 6 at % to 12 at. %

S: 1 at % to 5 at %

A thickness for effective operation as a selector or as a switch can be between 13 nm and 45 nm.

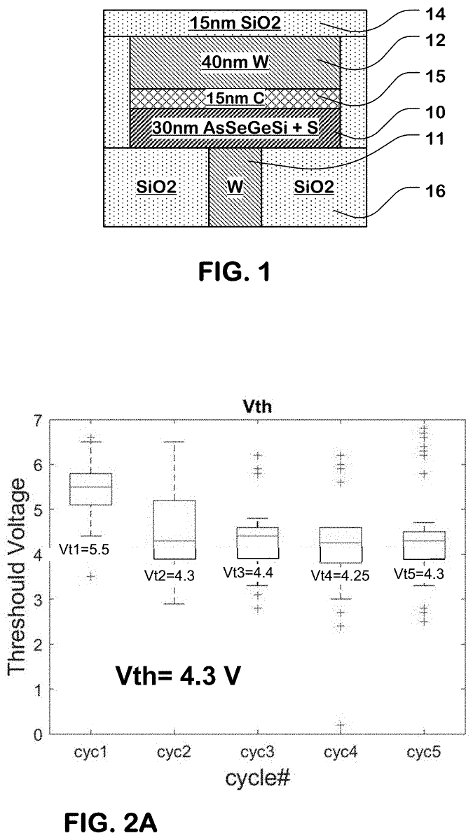

FIG. 1 is a simplified diagram of a switching device in a “mushroom cell” configuration, that includes a switching layer 10 of a selector material comprising S-doped AsSeGeSi as described herein. The switching layer for use as a switch on an integrated circuit has a thickness in a range from 13 to 45 nm. In this example, the switching layer has a thickness of 30 nm. The switching device includes a first electrode 11 and a second electrode 12, with a barrier layer 15 and the switching layer 10 in series between the first electrode and the second electrode, encapsulated in dielectric materials such as silicon dioxide 14, 16.

A voltage V1 can be applied to the first electrode 11, and a voltage V2 can be applied to the second electrode 12.

The first electrode 11 in this embodiment comprises a pillar of tungsten or other suitable electrode material, which contacts the switching layer on a first side with an area of contact. The second electrode 12 in this embodiment comprises a layer or line of tungsten or other suitable electrode material, which contacts the switching layer on a second side with an area of contact that is substantially larger than the area of contact of the first electrode on the switching layer.

The barrier layer 15 can provide one or more of resistance, adhesion and diffusion barrier functions. The barrier layer 15 can comprise carbon, including an in situ deposit of carbon, or other materials suitable for use as barrier materials. The barrier layer for use as a switch on an integrated circuit has a thickness in a range from 10 to 30 nm. In this example, the barrier layer has a thickness of 15 nm.

For the switching devices of FIG. 1, when the voltage (V1-V2) across the switching layer between the first electrode 11 and the second electrode 12 exceeds a threshold voltage of the switching layer, then the switching device is turned on. When the voltage across the first electrode 11 and the second electrode 12 is below a holding threshold voltage of the switching layer, the switching device returns to a high impedance, off state. The switching device shown in FIG. 1 can have a highly nonlinear current versus voltage IV characteristic, making them suitable for use as a switching or selector element in a high density memory device, and in other settings.

Other example materials for the barrier layer 15 can be a metal nitride, such as titanium nitride (TiN), tantalum nitride (TaN), tungsten nitride (WN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (WAlN), tantalum silicon nitride (TaSiN), or tantalum aluminum nitride (TaAlN). In addition to metal nitrides, the barrier layer 15 can comprise materials such as carbon/silicon, doped polysilicon, tungsten (W), copper (Cu), titanium (Ti), molybdenum (Mo), tantalum (Ta), titanium silicide (TiSi), tantalum silicide (TaSi), titanium tungsten (TiW), titanium oxynitride (TiON), titanium aluminum oxynitride (TiAlON), tungsten oxynitride (WON), or tantalum oxynitride (TaON).

A second barrier layer can be disposed on a second surface (e.g., bottom surface) opposite said first mentioned surface, of the ovonic threshold switch material, in some embodiments.

A class of compositions is described useful as a switching layer 10 in an integrated circuit, in which arsenic As, selenium Se, germanium Ge, silicon Si, and sulfur S are combined in amounts and with a thickness in the layer 10, effective to switch using an applied voltage pulse less than 50 ns in duration, such as less than 10 ns, at a threshold voltage Vt>3V. In some embodiments, the class of compositions described useful as a switching layer 10 in an integrated circuit, has arsenic As, selenium Se, germanium Ge, silicon Si, and sulfur S combined in amounts and with a thickness in the layer 10, effective to switch using an applied voltage pulse having a pulse width of less than 5 ns. A class of compositions is described useful as a switching layer 10 in an integrated circuit, in which arsenic As, selenium Se, germanium Ge, silicon Si, and sulfur S are combined in amounts and with a thickness in the layer 10, to have off-state leakage current I_{OFF}<2 nA. A class of compositions is described useful as a switching layer 10 in an integrated circuit, in which arsenic As, selenium Se, germanium Ge, silicon Si, and sulfur S are combined in amounts and with a thickness in the layer 10, effective to have off-state leakage current I_{OFF}<100 pA at 2V. In some embodiments, the class of compositions described useful as a switching layer 10 in an integrated circuit, has arsenic As, selenium Se, germanium Ge, silicon Si, and sulfur S combined in amounts and with a thickness in the layer 10, effective to switch using an applied voltage pulse less than 3V volts having a pulse width of less than 50 ns, and in some embodiments less than 5 ns, and to have off-state leakage current I_{OFF}<2 nA at 2V and in some embodiments <1 nA at 2V and in some embodiments <100 pA at 2V.

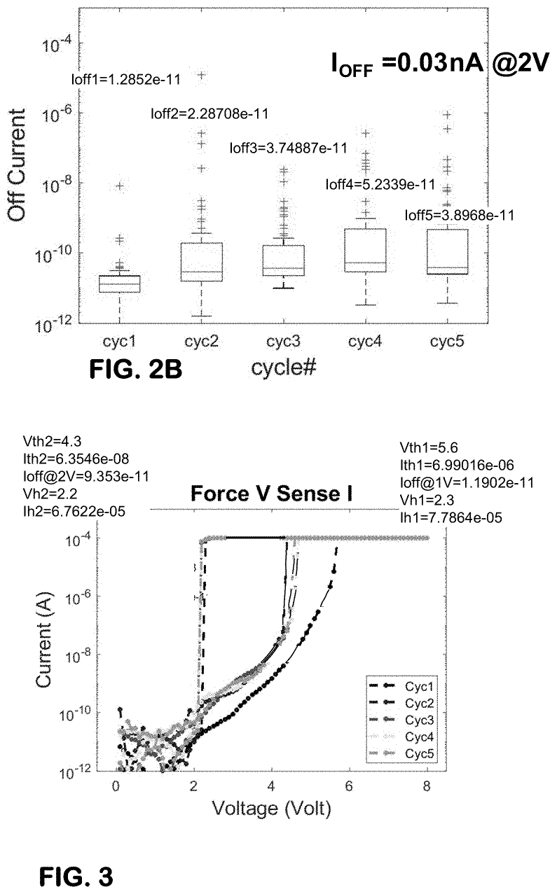

FIG. 2A is a box plot showing threshold voltage distributions for five cycles of a selector element like that of FIG. 1, using for 3 at. % S in AsSeGeSi material 30 nm thick. This test shows a threshold voltage about 4.3 volts after the first cycle. This material is effective as an OTS even with substantial oxygen incorporation (>20%).

FIG. 2B is a box plot showing off state current I_{OFF} distributions for five cycles of a selector element like that of FIG. 1, showing off state current I_{OFF} about of about 0.03 nA for a voltage across the switching layer of 2V after the first cycle. This material is effective as an OTS even with substantial oxygen incorporation (>20%).

A force voltage/sense current IV graph for cycling of the switch is shown in FIG. 3. The plot is generated by sweeping the voltage from 0V to 6V, and then from 6V to 0V, and measuring the current I. In the plot, a maximum of 100 μA is set for compliance so current is constant even as voltage increases for this region. The first cycle is a forming cycle, in which the threshold voltage is relatively high. In subsequent cycles the switch switches consistently at a threshold of about 4.3 V with a holding voltage Vh at about 2.2 V. This material is effective as an OTS even with substantial oxygen incorporation (>20%).

Comparative tests performed using a material without sulfur manufactured in a similar manner show short circuit after the first forming process, due to oxidation.

The test results shown in FIGS. 2A and 2B and 3 demonstrate effectiveness of the material for use as a selector element in an integrated circuit memory device, or as a switch in other integrated circuit devices. Using materials with better oxidation suppressed by increased sulfur up to about 5 at % may have even better performance characteristics.

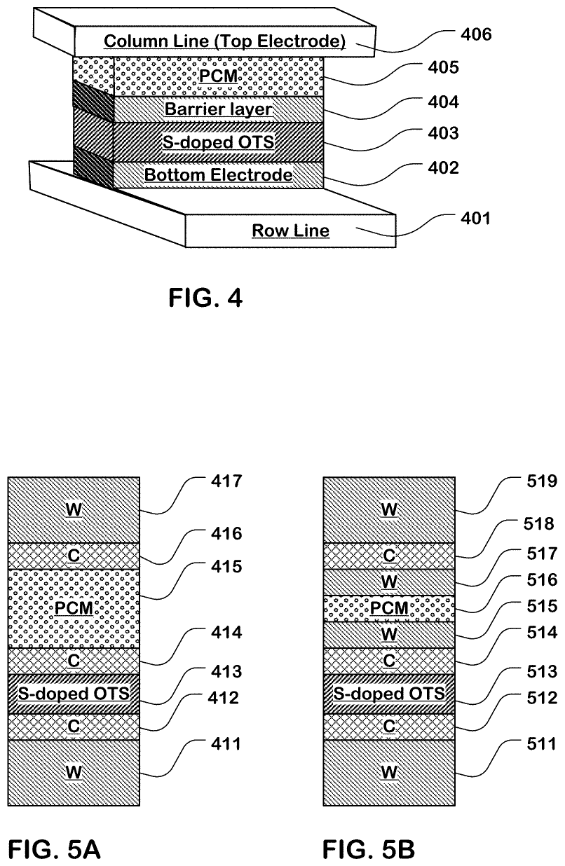

FIG. 4 illustrates an example memory cell which comprises a multi-layer pillar disposed in the crosspoint of a first access line (e.g. row line 401) and a second access line (e.g. column line 406).

The pillar in this example includes a bottom electrode layer 402, such as a metal, metal nitride, a doped semiconductor, or the like, on the row line 401.

An S-doped OTS switching layer 403, operable as a selector for the memory cell, is disposed on the bottom electrode 402. The OTS layer can be, for example, a layer of S-doped AsSeGeSi material having a thickness preferably less than 50 nm, and more preferably in a range of 15 to 45 nm.

A barrier layer 404 is disposed on the OTS switching layer 403, and can be called a capping layer for the OTS material. The barrier layer 404 can comprise a composition of carbon, or silicon and carbon, or other materials as discussed herein. The barrier layer 404 can be, for example, 15 to 30 nm thick.

A memory element 405 comprising a layer of memory material is disposed on the barrier layer 404. The memory material can comprise a programmable resistance material. In embodiments of the technology, the memory material comprises a phase change memory material, such as GST (e.g., Ge₂Sb₂Te₅), silicon oxide doped GST, nitrogen doped GST, silicon oxide doped GaSbGe, or other phase change memory materials. The memory element 405 can have a thickness selected according to the particular material utilized. For phase change material, an example range of thicknesses can be 5 to 50 nm thick. Some examples of memory materials that may be useful are disclosed in Ovshinsky, U.S. Pat. No. 5,687,112 at columns 11-13, which examples are incorporated by reference.

The memory element 405 can comprise a layer of chalcogenide alloy with additives to modify conductivity, transition temperature, melting temperature, and other properties. Representative additives can include nitrogen (N), silicon (Si), oxygen (O), silicon dioxide (SiOx), silicon nitride (SiN), copper (Cu), silver (Ag), gold (Au), aluminum (Al), aluminum oxide (Al₂O₃), tantalum (Ta), tantalum oxide (TaOx), tantalum nitride (TaN), titanium (Ti), and titanium oxide (TiOx).

In some embodiments, other programmable resistance memory elements can be implemented, such as metal-oxide resistive memories, magnetic resistive memories and conducting-bridge resistive memories, or other types of memory devices.

The first access lines (row lines) and the second access lines (column lines) can comprise a variety of metals, metal-like materials and doped semiconductors, or combinations thereof. Embodiments of the first and second access lines can be implemented using one or more layers of materials like tungsten (W), aluminum (Al), copper (Cu), titanium nitride (TiN), tantalum nitride (TaN), tungsten nitride (WN), doped polysilicon, cobalt silicide (CoSi), Tungsten silicide (WSi), TiN/W/TiN, and other materials. For example, the thicknesses of the first access lines and the second access lines can range from 10 to 100 nm. In other embodiments, the first access lines and the second access lines can be very thin, or much thicker. The material selected for the second access lines is preferably selected for compatibility with the memory element 405. Likewise, the material selected for the first access lines is preferably selected for compatibility with the layer 402.

In another embodiment, a bottom electrode like that shown in FIG. 1, having a smaller contact surface than the surface of the memory element, is interposed between the memory element 405 and the switching layer 403 or between the memory material layer 405 and the top electrode (column line 406). As such, an increased current density at the contact in the memory element can be achieved.

Memory cells can be organized in a crosspoint architecture, such as described in U.S. Pat. No. 6,579,760, entitled Self-Aligned, Programmable Phase Change Memory, issued 17 Jun. 2003, which is incorporated by reference herein. The first electrode can be the access lines, such as word lines and/or bit lines. In such architecture, the access devices are arranged between the switching devices and the access lines.

FIGS. 5A and 5B show alternative stacks of materials including an S-doped OTS layer as described herein and a memory layer, suitable for use in cross-point arrays. These stack configurations are representative of a range of suitable configurations that can be implemented according to operational and manufacturing considerations.

In FIG. 5A, a memory cell is disposed between conductors 411 and 417, each of which may comprise, for example, tungsten W. A barrier layer 412, such as carbon, is disposed in contact with the conductor 411. An S-doped OTS material layer 413 is disposed in contact with the barrier layer 412. A barrier layer 414 is disposed in contact with the S-doped OTS material layer 413. A phase change memory PCM material layer 415 is disposed in contact with the barrier layer 414. A barrier layer 416 is disposed in contact with the PCM material layer 415. The conductor 417 is disposed in contact with the barrier layer 416. The barrier layers 416, 414 and 412 can all comprise carbon, or other suitable material.

In FIG. 5B, a memory cell is disposed between conductors 511 and 519, each of which may comprise for example tungsten W. A barrier layer 512, such as carbon, is disposed in contact with the conductor 511. An S-doped OTS material layer 513 is disposed in contact with the barrier layer 512. A barrier layer 514 is disposed in contact with the S-doped OTS material layer 513. An electrode layer 515, such as tungsten or other conductor suitable for contact with the material of the memory layer, is disposed in contact with the barrier layer 514. A phase change memory PCM material layer 516 is disposed in contact with the electrode layer 515. Another electrode layer 517 is conductor disposed in contact with the PCM material layer 516. The electrode layer 517 is a conductor disposed in contact with the barrier layer 516. A barrier layer 518 is disposed in contact with the electrode layer 517. The conductor 519 is disposed in contact with the barrier layer 518. The barrier layers 518, 514 and 512 can all comprise carbon, or other suitable material.

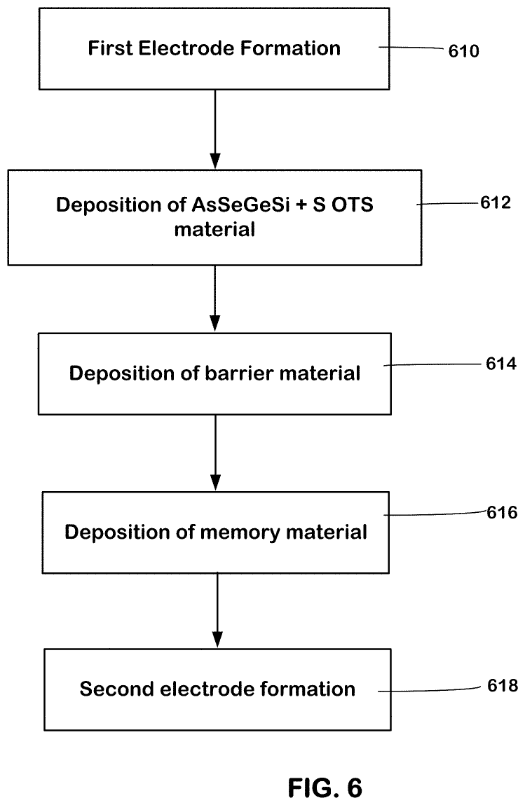

FIG. 6 is a simplified flowchart of a manufacturing process for a memory device including a S-doped AsSeGeSi OTS material as described herein.

At step 610, a first electrode is formed including materials as described above, with an optional barrier layer, and patterning techniques such as discussed in the references incorporated by reference.

At step 612, a switching layer including an S-doped AsSeGeSi OTS material, including materials described above, for example, is formed in a sputtering chamber of a sputtering system, having targets consisting of the selected materials. In some embodiments, the S-doped AsSeGeSi material is deposited using a single sputter target for the OTS material consisting of the S, As, Se, Ge and Si in combinations determined empirically to result in the desired concentrations of materials as discussed herein.

At step 614, deposition of a barrier layer including, for example, a carbon as described above is formed. In a preferred example, the composition is formed by in situ sputtering in the same sputtering chamber as the OTS material using a pure carbon sputter target.

At step 616, a memory material is formed on the barrier layer. The memory material can be a programmable resistance material, like a phase change material, or other materials as described above.

At step 618, a second electrode is formed. The second electrode can be formed by deposition and patterned etch, for example, of a conductive material.

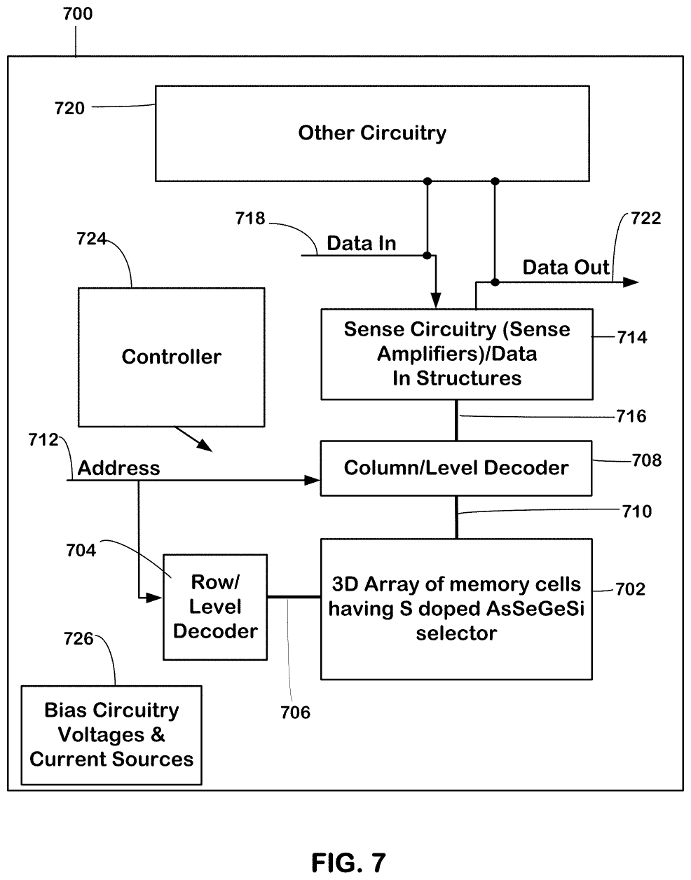

A device can be completed using back-end-of-line (BEOL) processing. The BEOL process is to complete the semiconductor process steps of the chip, including in some manufacturing technologies, exposing the materials to temperatures on the order of 400° C. or more. The BEOL processes can be standard processes as known in the art, and the processes performed depend upon the configuration of the chip in which the switching device is implemented. Generally, the structures formed by BEOL processes may include contacts, inter-layer dielectrics and various metal layers for interconnections on the chip, including circuitry to couple the switching device to peripheral circuitry. As a result of these processes, control circuits and biasing circuits as shown in FIG. 7 are formed on the device.

FIG. 7 is a simplified block diagram of an integrated circuit 700 including a 3D array 702 of crosspoint memory cells having S-doped AsSeGeSi switching layers (OTS switch) as described herein, with programmable resistance memory layers. A row/level line decoder 704 having read, set and reset modes is coupled to, and in electrical communication with, a plurality of word lines 706 arranged in levels and along rows in the array 702. A column/level decoder 708 is in electrical communication with a plurality of bit lines 710 arranged in levels and along columns in the array 702 for reading, setting, and resetting the memory cells in the array 702. Addresses are supplied on bus 712 to row/level decoder 704 and column/level decoder 708. Sense circuitry (Sense amplifiers) and data-in structures in block 714, including voltage and/or current sources for the read, set, and reset modes are coupled to decoder 708 via data bus 716. Data is supplied via a data-in line 718 from input/output ports on integrated circuit 700, or from other data sources internal or external to integrated circuit 700, to data-in structures in block 714. Other circuitry 720 may be included on integrated circuit 700, such as a general purpose processor or special purpose application circuitry, or a combination of modules providing system-on-a-chip functionality supported by array 702. Data is supplied via a data-out line 722 from the sense amplifiers in block 714 to input/output ports on integrated circuit 700, or to other data destinations internal or external to integrated circuit 700.

A controller 724 implemented in this example, using a bias arrangement state machine, controls the application of bias circuitry voltage sources and current sources 726 for the application of bias arrangements, including read, set, reset and verify voltages, and/or currents for the word lines and bit lines. The controller includes control circuitry configured for switching layers as described herein, depending on the structure and composition of the switching layer, by applying a voltage to a selected memory cell so that the voltage on the switch in the select memory cell is above the threshold, and a voltage to an unselected memory cell so that the voltage on the switch in the unselected memory cell is below the threshold during a read operation or other operation accessing the selected memory cell.

Controller 724 may be implemented using special-purpose logic circuitry as known in the art. In alternative embodiments, controller 724 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 724.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A switching device, comprising:
a first electrode;
a second electrode; and
a switching layer between the first and second electrodes, the switching layer comprising a composition including a chalcogenide having an additive effective to suppress oxidation.

2. The device of claim 1, wherein the composition includes arsenic, and the additive is sulfur.

3. The device of claim 1, wherein the composition includes arsenic and silicon, and the additive is sulfur.

4. The device of claim 1, wherein the composition includes selenium, and the additive is sulfur.

5. The device of claim 1, wherein the composition includes selenium and silicon, and the additive is sulfur.

6. The device of claim 1, wherein the composition includes arsenic, selenium and silicon, and the additive is sulfur.

7. The device of claim 1, wherein the composition includes arsenic As in a range of 25 at % to 33 at %, selenium Se in a range of 34 at % to 46 at %, germanium Ge in a range of 8 at % to 12 at %, silicon Si in a range of 6 at % to 12 at % and sulfur S in a range of 1 at % to 5 at %.

8. The device of claim 7, wherein the composition includes As, Se, Ge, Si and S in amounts effective to switch using an applied voltage pulse less than 50 ns in duration at a threshold voltage Vt>3V.

9. The device of claim 7, wherein the composition includes As, Se, Ge, Si and S in amounts effective to have off-state leakage current I_{OFF}<2 nA at 2V.

10. The device of claim 7, wherein the composition includes As, Se, Ge, Si and S in amounts effective to have off-state leakage current I_{OFF}<100 pA at 2V.

11. The device of claim 1, wherein the switching layer is less than 50 nm thick.

12. The device of claim 1, wherein the switching layer has a thickness in a range of 13 to 45 nm, inclusive.

13. A memory device, comprising:
a first electrode;
a second electrode;
a memory element in contact with the first electrode;
a selector between the first and second electrodes, the selector comprising a composition of arsenic As in a range of 25 at % to 33 at %, selenium Se in a range of 34 at % to 46 at %, germanium Ge in a range of 8 at % to 12 at %, silicon Si in a range of 6 at % to 12 at % and sulfur S in a range of 1 at % to 5 at %; and
a barrier layer between the memory element and the selector.

14. The device of claim 13, wherein the composition includes As, Se, Ge, Si and S in amounts effective to switch using an applied voltage pulse less than 50 ns in duration at a threshold voltage Vt>3V.

15. The device of claim 13, wherein the composition includes As, Se, Ge, Si and S in amounts effective to have off-state leakage current I_{OFF}<1 nA.

16. The device of claim 13, wherein the composition includes As, Se, Ge, Si and S in amounts effective to have off-state leakage current I_{OFF}<100 pA at 2 V.

17. The device of claim 13, wherein the selector is less than 50 nm thick.

18. The device of claim 13, wherein the selector has a thickness in a range of 13 to 45 nm, inclusive.

19. The device of claim 13, wherein the memory element comprises a programmable resistance material.

20. An integrated circuit memory device, comprising:
a cross-point array of memory cells, memory cells in the cross point array each comprising a first electrode; a second electrode; a memory element in contact with the first electrode; and a selector between the first and second electrodes, the selector comprising a composition including a chalcogenide having an additive effective to suppress oxidation.
